(19) United States
(12) Patent Application Publication
(10) Pub. No.: US 2026/0056418 A1
(43) Pub. Date: Feb. 26, 2026

(54) OVERMOLDED GROMMET FOR FLEXIBLE PRINTED CIRCUIT SEALING THROUGH HINGES IN WEARABLE DEVICES, AND SYSTEMS AND METHODS OF USE THEREOF

(71) Applicant: Meta Platforms Technologies, LLC, Menlo Park, CA (US)

(72) Inventors: Isaac Finger, Sunnyvale, CA (US); Michael Webb, Scotts Valley, CA (US); Yuanjing Zheng, Qingdao (CN)

(21) Appl. No.: 19/301,839

(22) Filed: Aug. 15, 2025

Related U.S. Application Data
(60) Provisional application No. 63/686,627, filed on Aug. 23, 2024.

(51) Int. Cl. G02B 27/01; F16J 15/02; H05K 5/06

(52) U.S. Cl. CPC G02B 27/0176; F16J 15/021; H05K 5/065; G02B 2027/0178

(57) ABSTRACT

An extended-reality headset is disclosed herein. The extended-reality headset including a frame portion including one or more electrical components, a temple arm including one or more additional electrical components. The frame portion is coupled, via a hinge, to the temple arm. The extended-reality headset further includes a flexible printed circuit configured to couple at least one of the one or more additional electrical components of the temple arm with at least one of the one or more electrical components of the frame. The flexible printed circuit (FPC) incudes (i) an overmolded temple grommet configured to seal the one or more additional electrical components of the temple arm, and (ii) an overmolded frame grommet configured to seal the one or more electrical components of the frame. The FPC is further configured to move with the movement of the temple arm relative to the frame portion.

### RELATED APPLICATION

This application claims priority to U.S. Provisional Application Ser. No. 63/686,627, filed Aug. 23, 2024, entitled “Overmolded Grommet For Flexible Printed Circuit Sealing Through Hinges In Wearable Devices, And Systems And Methods Of Use Thereof,” which is incorporated herein by reference.

### TECHNICAL FIELD

This relates generally to the sealing of extended-reality electronics from exposure to liquid and debris from a surrounding environment, including but not limited to techniques for safeguarding electronics by sealing the hinges using grommets to prevent liquid and debris contact.

### BACKGROUND

When users wear and use head-worn devices with integrated electronics, the electronics face potential exposure to fluid and/or debris from the user's sweat, rain, accidental immersion, dust, dirt, etc. Current headset devices are designed for primarily indoor use only or if used outdoors are intended to not come in contact with moisture or debris from the surrounding environment. Using one of these current designs outside for extended periods could result in a reduced lifespan of the device due to moisture and debris ingress to sensitive electrical components of the device. Accordingly, there is a need for safeguarding electronics in head-wearable devices from moisture and debris ingress.

As such, there is a need to address one or more of the above-identified challenges. A brief summary of solutions to the issues noted above are described below.

### SUMMARY

The devices described herein create a liquid and debris tight seal at a frame and a temple of an extended-reality headset arm where the frame and temple arm are hingeably coupled together. This liquid and debris seal is produced by using a overmolded grommet(s) coupled to the flexible printed circuit (FPC) board. This allows the electronics coupled to an FPC integrated into the frame and/or the temple arm of the extended-reality device to have no fluid or debris contact. This maintains the integrity of the electronics coupled to the FPC.

One example extended-reality headset described herein includes a frame portion that includes one or more electrical components and a temple arm that includes one or more additional electrical components. The frame portion is coupled, via a hinge, to the temple arm. The extended-reality headset further includes a flexible printed circuit configured to couple at least one of the one or more additional electrical components of the temple arm with at least one of the one or more electrical components of the frame. The FPC incudes (i) an overmolded temple grommet configured to seal the one or more additional electrical components of the temple arm, and (ii) an overmolded frame grommet configured to seal the one the one or more electrical components of the frame. The FPC is further configured to move with the movement of the temple arm relative to the frame portion.

An example method of manufacturing an extended-reality headset is described herein. The method includes connecting a frame portion of the extended-reality device to a temple arm portion of the extended-reality device, via a hinge. Both the frame portion and the temple arm portion of the extended-reality device includes one or more electrical components contained inside their respective portions. The method further includes coupling, via an FPC, at least one of the one or more additional electrical components of a temple arm with at least one of the one or more electrical components of the frame. The method further includes overmolding an overmolded temple grommet onto a first portion of the FPC. The overmolded temple grommet is configured to seal the one or more additional electrical components of the temple arm. The method further includes overmolding an overmolded frame grommet onto a second portion of the FPC. The overmolded frame grommet is configured to seal one of the one or more electrical components of the frame.

The features and advantages described in the specification are not necessarily all inclusive and, in particular, certain additional features and advantages will be apparent to one of ordinary skill in the art in view of the drawings, specification, and claims. Moreover, it should be noted that the language used in the specification has been principally selected for readability and instructional purposes.

Having summarized the above example aspects, a brief description of the drawings will now be presented.

### BRIEF DESCRIPTION OF THE DRAWINGS

The patent or application file contains at least one drawing executed in color. Copies of this patent or patent application publication with color drawings will be provided by the Office upon request and payment of the necessary fee.

For a better understanding of the various described embodiments, reference should be made to the Detailed Description below, in conjunction with the following drawings in which like reference numerals refer to corresponding parts throughout the figures.

FIG. 1A - 1C illustrate examples of one or more overmolded grommets coupled to a flexible printed circuit, in accordance with some embodiments.

FIGS. 2A-1 and 2A-2 illustrate an example method of insertion of the overmolded grommet into a hinge of the extended-reality device, in accordance with some embodiments.

FIG. 2B illustrates examples of shapes of an overmolded grommet, in accordance with some embodiments.

FIG. 3 shows an example method flow chart for manufacturing an overmolded grommet, in accordance with some embodiments.

FIGS. 4A, 4B-1, 4B-2, and 4C illustrate example head-wearable devices, in accordance with some embodiments.

In accordance with common practice, the various features illustrated in the drawings may not be drawn to scale. Accordingly, the dimensions of the various features may be arbitrarily expanded or reduced for clarity. In addition, some of the drawings may not depict all of the components of a given system, method, or device. Finally, like reference numerals may be used to denote like features throughout the specification and figures.

### DETAILED DESCRIPTION

Numerous details are described herein to provide a thorough understanding of the example embodiments illustrated in the accompanying drawings. However, some embodiments may be practiced without many of the specific details, and the scope of the claims is only limited by those features and aspects specifically recited in the claims. Furthermore, well-known processes, components, and materials have not necessarily been described in exhaustive detail so as to avoid obscuring pertinent aspects of the embodiments described herein.

Embodiments of this disclosure can include or be implemented in conjunction with various types or embodiments of artificial-reality (AR) systems. AR, as described herein, is any superimposed functionality and or sensory-detectable presentation provided by an AR system within a user's physical surroundings. Such AR can include and/or represent virtual reality (VR), augmented reality, mixed AR, or some combination and/or variation of one or more of these. For example, a user can perform a swiping in-air hand gesture to cause a song to be skipped by a song-providing API providing playback at, for example, a home speaker. An AR environment, as described herein, includes, but is not limited to, VR environments (including non-immersive, semi-immersive, and fully immersive VR environments); augmented-reality environments (including marker-based augmented-reality environments, markerless augmented-reality environments, location-based augmented-reality environments, and projection-based augmented-reality environments); hybrid reality; and other types of mixed-reality environments.

AR content can include completely generated content or generated content combined with captured (e.g., real-world) content. The AR content can include video, audio, haptic events, or some combination thereof, any of which can be presented in a single channel or in multiple channels (such as stereo video that produces a three-dimensional (3D) effect to a viewer). Additionally, in some embodiments, AR can also be associated with applications, products, accessories, services, or some combination thereof, which are used, for example, to create content in an AR and/or are otherwise used in (e.g., to perform activities in) an AR.

A hand gesture, as described herein, can include an in-air gesture, a surface-contact gesture, and/or other gestures that can be detected and determined based on movements of a single hand (e.g., a one-handed gesture performed with a user's hand that is detected by one or more sensors of a wearable device (e.g., electromyography (EMG) and/or inertial measurement units (IMUs) of a wrist-wearable device) and/or detected via image data captured by an imaging device of a wearable device (e.g., a camera of an extended-reality device)) or a combination of the user's hands. In-air means, in some embodiments, that the user's hand does not contact a surface, object, or portion of an electronic device (e.g., an extended-reality device or other communicatively coupled device, such as the wrist-wearable device); in other words the gesture is performed in open air in 3D space and without contacting a surface, an object, or an electronic device. Surface-contact gestures (contacts at a surface, object, body part of the user, or electronic device) more generally are also contemplated in which a contact (or an intention to contact) is detected at a surface (e.g., a single-or double-finger tap on a table, on a user's hand or another finger, on the user's leg, a couch, a steering wheel, etc.). The different hand gestures disclosed herein can be detected using image data and/or sensor data (e.g., neuromuscular signals sensed by one or more biopotential sensors (e.g., EMG sensors) or other types of data from other sensors, such as proximity sensors, time-of-flight (ToF) sensors, sensors of an IMU, etc.) detected by a wearable device worn by the user and/or other electronic devices in the user's possession (e.g., smartphones, laptops, imaging devices, intermediary devices, and/or other devices described herein).

As described herein, a method of water sealing integrated electronics within an extended-reality device is disclosed. The methods and devices described herein include methods and systems for coupling an overmolded grommet to a flexible printed circuit (FPC) and inserting the overmolded grommet into the hinge of the extended-reality device to provide a watertight seal.

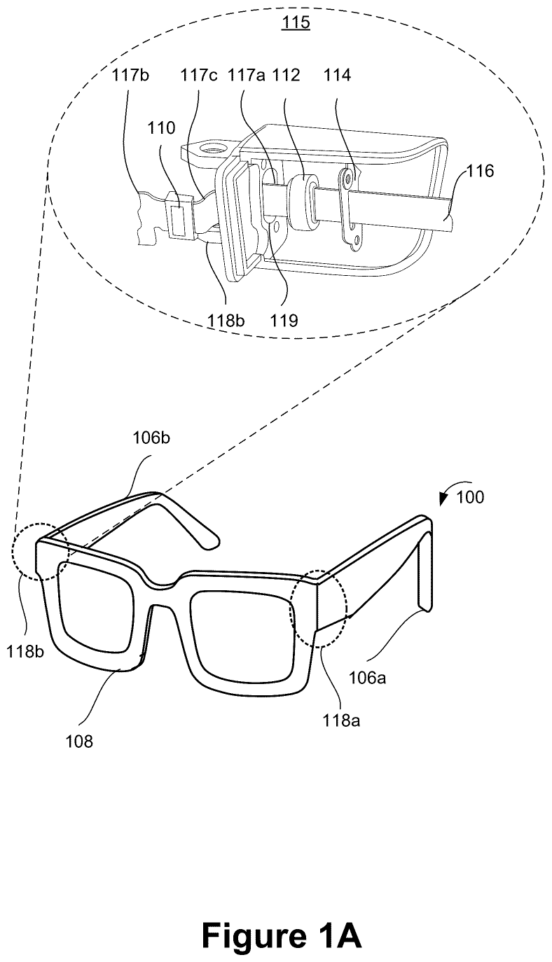

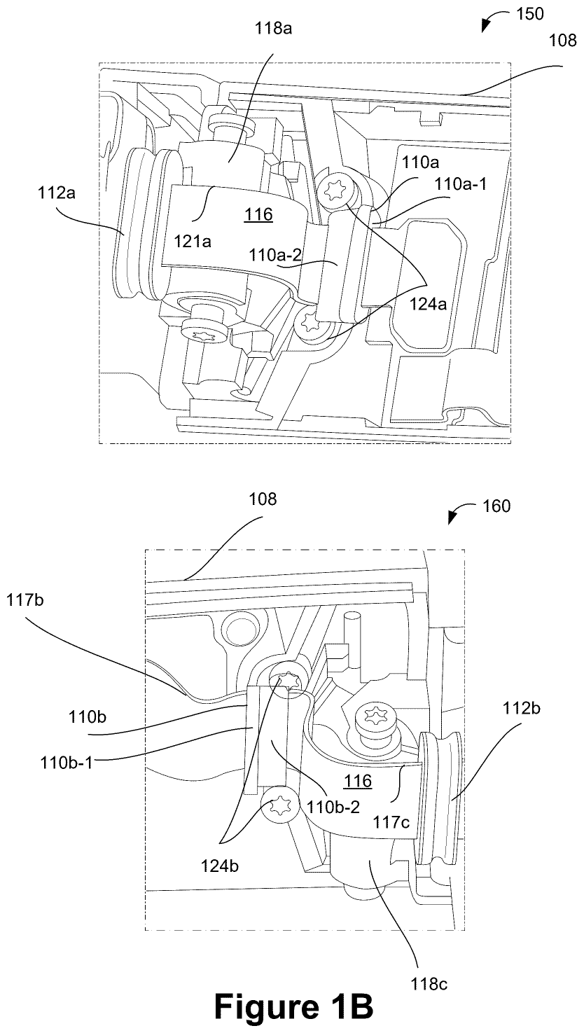

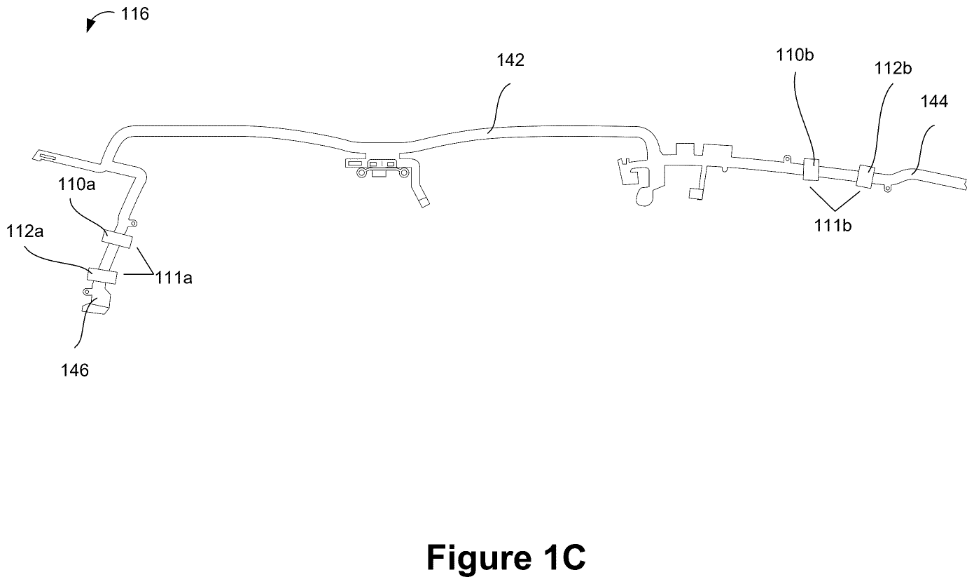

FIG. 1A-1C illustrate examples of one or more overmolded grommets coupled to an FPC, in accordance with some embodiments. FIG. 1A further illustrates an extended-reality device 100 (e.g., smart/augmented reality glasses) including a first temple arm 106a and a second temple arm 106b that are each hingeably coupled to a frame 108 to produce the extended-reality device 100. The first temple arm 106a and the second temple arm 106b are coupled to the frame 108 via a first hinge 118a and a second hinge 118b. In other words, the first temple arm 106a is coupled to the frame 108 via a first hinge 118a and the second temple arm 106b is coupled to the frame 108 via a second hinge 118b. The first hinge 118a and second hinge 118b, for example, can mirror each other and have similar components at opposite ends of the frames. The first hinge 118a and the second hinge 118b can have portions that are integrally formed (e.g., a continuous piece) with the frame 108, and the first temple arm 106a and the second temple arm 106b can be integrally formed with other portions of the first hinge 118a and the second hinge 118b, respectively. An FPC 116 (partially illustrated in exploded view 115) is integrated into the extended-reality device 100 inside of the first and second temple arms 106a and 106b and the frame 108. As shown in exploded view 115, a first portion 117a of the FPC 116 is housed within the second temple arm 106b and a second portion 117b of the FPC is housed in the frame 108, and an intermediary portion 117c of the FPC 116 is located within the second hinge 118b that is placed between the temple arm 106b and the frame 108. In another example, the FPC 116 can be a continuous piece that follows a path from the first temple arm to the frame to the second temple arm (as described in reference to FIG. 1C) or the FPC 116 can be multiple FPCs coupled together (e.g., a portion that is primarily housed within the first temple arm, the second temple arm, and the frame). The intermediary portion 117c is configured to pass through the hinge and is configured to bend with the hinge 118b as it transitions between positional states.

FIG. 1A further illustrates an exploded view 115 with two overmolded grommets (e.g., a first temple-arm overmolded grommet 112 and a first frame-overmolded grommet 110) that prevent liquid and debris from entering the interior of the frame 108 and the interior of the temple arm 106b. The temple-arm overmolded grommet 112 is configured to interface with an outlet 119 of the temple arm 106b to produce a seal while still allowing the FPC 116 to exit the second temple arm 160b. The intermediary portion 117c of the FPC 116 that is in hinge can be coated to prevent liquid and debris from interacting with the FPC 116, as this portion of the FPC 116 can be exposed to the surrounding environment. In some embodiments, the entirety of the FPC 116 is coated outside of connection points. The process of overmolding the temple-arm overmolded grommet 112 onto the FPC 116 creates a seal that is both liquid and debris resistant and at a minimum is as resistant to liquid and debris ingress as the seal produced by the temple-arm overmolded grommet 112 interfacing with the outlet 119. In some embodiments, glue can also be used to further secure the temple-arm overmolded grommet 112.

The frame overmolded grommet 110 performs a similar function to the overmolded grommet 112 of the first temple arm 106a of sealing an interior cavity of the frame 108 that protects electronics from liquid and debris. The frame overmolded grommet 110 can also be secured in place using similar techniques to those described in refence to the temple-arm overmolded grommet 112.

Furthermore, the FPC 116 is unable to slide through the frame overmolded grommet 110 or the temple overmolded grommet 112. During manufacturing, the frame and temple overmolded grommets 110 and 112 are coupled directly to the FPC 116 and overmolded onto their respective portions of the FPC 116. The frame overmolded grommet 110 and the temple-arm overmolded grommet 112 are composed of at least one of silicone rubber or liquid rubber configured to create a liquid-and debris-sealing effect. In some embodiments, the temple-arm overmolded grommet 112 and the frame overmolded grommet 110 are the same shape and size or are two distinct shapes. While the above descriptions describe a single temple arm, first temple arm 106a, the second temple arm 106a is understood to have the same capabilities. Subsequent discussions on temple arms are intended to refer to capabilities of both the first and second temple arms.

As alluded to above, the FPC 116 has slack between the frame overmolded grommet 110 and the temple-arm overmolded grommet 112 such that the user can actuate the first and/or second temple arm 106a and 106b to open and close. The section of the FPC 116 between the frame overmolded grommet 110 and the temple-arm overmolded grommet 112 has enough slack such that if the glasses are open, closed, or overextended (e.g., up to 10% angular extension beyond the open or closed positions) the FPC 116 is not damaged. As the FPC 116 moves while the user actuates the temple arm, the portion of the FPC housed in the temple arm does not move relative to the temple arm and the portion of the FPC housed in the frame does not move relative to the frame.

As discussed above, the temple arms are configured to operate between at least a first positional state relative to the frame portion and a second positional state relative to the frame portion. For example, a first positional state includes when the temple arms 106a and 106b are in the open position as shown in FIG. 1A and a second position includes when the temple arms 106a and 106b are folded in a closed position.

In some embodiments, when the temple arms 106a and 106b are either in the open or closed position the frame and temple-arm overmolded grommets 110 and 112 are configured to seal one or more electronics of the temple arm or the frame 108. For example, while the first temple arm 106a is in the first open position, the frame overmolded grommet 110 is configured to seal the one or more components of the frame 108. The frame overmolded grommet 110 and the temple-arm overmolded grommet 112 and their respective interface locations are configured such that the same sealing effectiveness is capable in either the opened or closed positions. This is achieved by ensuring that the intermediary portion 117c of the FPC 116 is oversized enough that the positional state does not cause further load on either the frame overmolded grommet 110 or the temple-arm overmolded grommet 112.

FIG. 1A further illustrates a cowling 114 that is configured to hold and secure the temple-arm overmolded grommet 112 into place. This cowling 114 can be secured via screws, adhesives, clips, etc. The temple-arm overmolded grommet 112 is secured in place through a combination of an interference fit within the outlet 119 and one or more features that mechanically limit the movement of the temple-arm overmolded grommet 112. The temple-arm overmolded grommet 112 is secured in place within the temple arm 106b from the friction/interference fit between the outlet 119 and the temple-arm overmolded grommet 112.

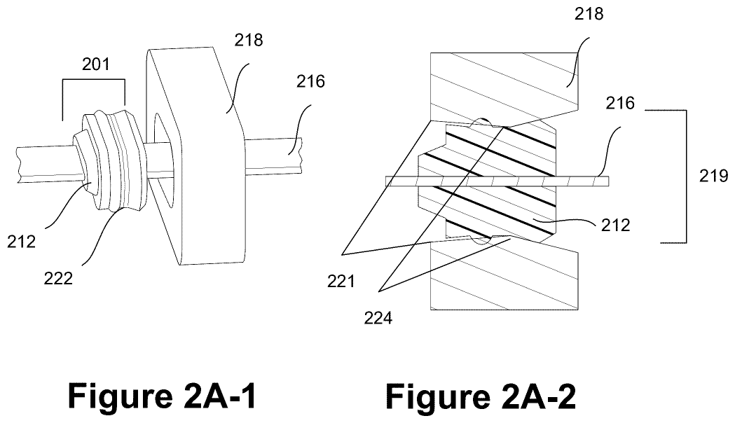

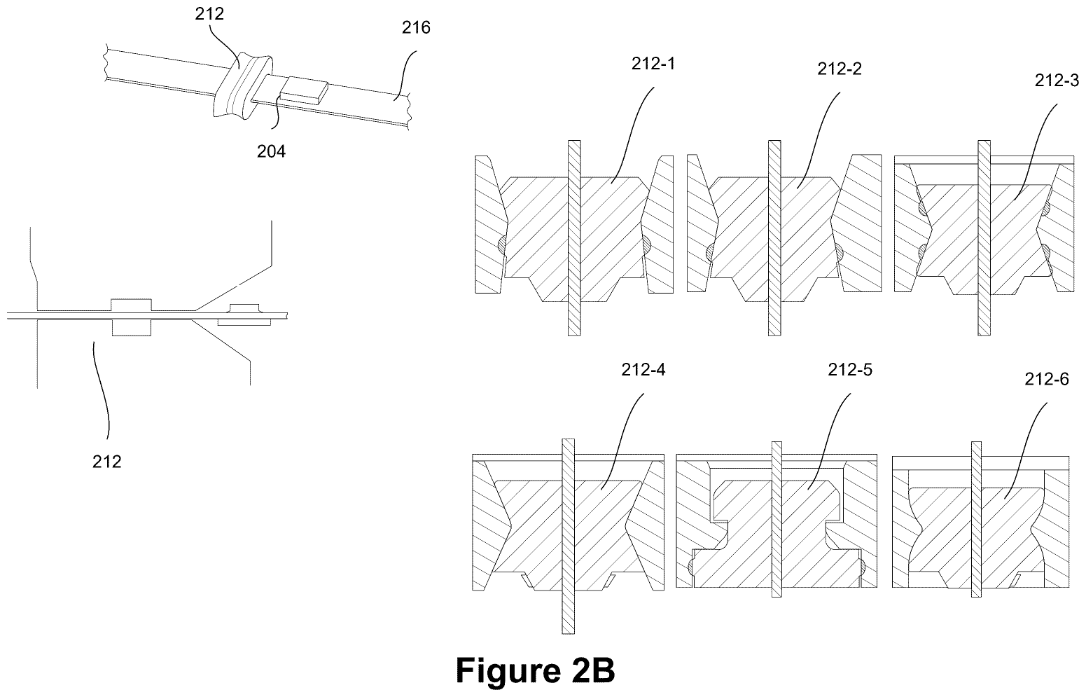

This is further illustrated and discussed with respect to FIG. 2A where the grommet can have a shape and the outlet 119 can have a shape that when the temple-arm overmolded grommet 112 is inserted into the outlet the combination resists removal. This interference fit alone can produce a fluid and dust seal. A cowling 114 can be positioned behind the temple-arm overmolded grommet 112 on the interior side of the temple arm to constrain the temple-arm overmolded grommet 112 from movement (e.g., sandwiching the temple-arm overmolded grommet 112 between the temple arm 106b and the cowling). In some embodiments, the cowling 114 is coupled to the temple arm 106b using one or more of a screw, clips, adhesives, etc. In some embodiments, another cowling is placed on the exterior side of the temple arm to further constrain the temple-arm overmolded grommet 112 from movement. In some embodiments, the outlet 119 has a wider passage on the interior side of the temple arm 106b and narrower passage on the exterior side of the temple arm 106b, such that the temple-arm overmolded grommet 112 cannot be entirely passed through the outlet 119 but the FPC 116 can be passed through.

In some embodiments, an adhesive can be added to further secure the temple-arm overmolded grommet 112. In a different embodiment, an overmolded grommet on an FPC 116 is not used to create a watertight seal and instead a glue (e.g., silicone based) is inserted into the hinge 118 to hold the FPC 116 in place and seal the hinge 118 opening.

FIG. 1B illustrates exploded views of the right-side hinge assembly and the left-side hinge assembly, in accordance with some embodiments. The exploded view of the left-side hinge assembly 150 includes the first hinge 118a, a first temple-arm overmolded grommet 112a, a first frame overmolded grommet 110a, and an intermediary portion 121a of the FPC 116 located within the first hinge 118a that is placed between the first temple-arm overmolded grommet 112a and the first frame overmolded grommet 110a. The exploded view of the right-side hinge assembly 160 includes a third hinge 118c, a second temple-arm overmolded grommet 112b, a second frame overmolded grommet 110b, and an intermediary portion 117c of the FPC 116 located within the third hinge 118c that is placed between the second temple-arm overmolded grommet 112b and second frame overmolded grommet 110b. The right-side hinge assembly 160 is an instance of the exploded view 115 that includes the second hinge 118b; however, the exploded view of the right-side hinge assembly 160 omits the cowling 114 that is illustrated in the exploded view 115 with second hinge 118b in FIG. 1A. The third hinge 118c includes all of the features mentioned in reference to the second hinge 118b above. Additionally, as mentioned above in FIG. 1A, the temple-arm grommet 112 is self-placing and does not require a cowling 114 to secure the temple-arm grommet 112 to the hinge.

The frame overmolded grommet 110 illustrated in FIG. 1A is illustrated as the first frame overmolded grommet 110a and the second frame overmolded grommet 110b in FIG. 1B. The first and second frame overmolded grommets 110a and 110b are configured to interface with a respective first and second outlet portions 124a and 124b of the frame 108. In some embodiments, the first and second outlet portions 124a and 124b of the frame 108 are at least screws, posts, or a portion of the frame 108 that creates an opening such that the first and second frame overmolded grommets 110a and 110b are coupled such that a liquid-and debris-tight seal is created. Similar to the first and second temple-arm overmolded grommets 112a and 112b, the seal created between the first and second outlet portion 124a and 124b of the frame 108 and the first and second frame overmolded grommets 110a and 110b are liquid and debris tight such that the one or more electronics (e.g., a first set of components 142 coupled to the frame portion of the FPC 116) housed inside of the frame 108 will not be damaged. In some embodiments, the first and second outlet portions 124a and 124b of the frame 108 are composed of screws or other hardware pieces coupled to the hinge.

In some embodiments, the first ends 110a-1 and 110b-1 of the first and second frame overmolded grommets 110a and 110b are wider than the second ends 110a-2 and 110b-2 such that during manufacturing, the first ends 110a-1 and 110b-1 of the first and second frame overmolded grommets 110a and 110b can be pulled/pushed through the first and second outlet portions 124a and 124b of the frame 108 and sealed when the first ends 110a-1 and 110b-1 pass through the first and second outlet portions 124a and 124b. Furthermore, the first ends 110a-2 and 110b-2 of the first and second frame overmolded grommets 110a and 110b are configured such that once the first and second frame overmolded grommets 110a and 110b are placed, it will require more force to remove them from the first and second outlet portions 124a and 124b than was required to place them.

FIG. 1C illustrates the FPC 116 that has four overmolded grommets coupled to the FPC 116 (i.e., two for each side of the headset). FIG. 1C further illustrates a first temple-arm overmolded grommet 112a, a first frame overmolded grommet 110a, a second temple-arm overmolded grommet 112b, and a second frame overmolded grommet 110b. The first and second temple-arm overmolded grommets 112a and 112b include all of the features of the temple-arm overmolded grommet 112 discussed in FIG. 1A. The first and second frame overmolded grommets 110a and 110b include all of the features of the frame overmolded grommet 110 discussed in FIG. 1A. While FIG. 1C illustrates the FPC 116 as one continuous piece, it is understood that the FPC can be segmented and connected together to achieve the same result.

FIG. 1C further illustrates that a gap 111a and a gap 111b exist between the temple-arm overmolded grommet 112 and the frame overmolded grommet 110 that passes through a hinge region. The length of the FPC 116 at gaps 111a and 111b is a distance greater than or equal to 10 mm, which provides slack to the FPC 116 to allow the temple arms 106a and 106b to be moved from the opened to closed position or vice versa. The slack is selected to minimize force on the FPC and the frame and temple-arm overmolded grommets 210 and 212, thereby ensuring repeated use is possible without impacting the electrical performance of the FPC 116 and the sealing capabilities of the grommets.

FIG. 1C further illustrates a first set of components 142 coupled to the frame portion of the FPC 116, a second set of components 146 coupled to a first temple-arm portion of the FPC 116, and a third set of components 144 coupled to the second temple-arm portion of the FPC 116. The first, second and third sets of components 142 - 146 are electrically coupled together via the FPC 116.

FIGS. 2A-1 and 2A-2 illustrate an example method of insertion of the overmolded grommet into a hinge of the extended-reality device, in accordance with some embodiments. FIG. 2A-1 illustrates an outlet 219 of a temple arm and a temple-arm overmolded grommet 212 prior to insertion, and FIG. 2A-2 illustrates the outlet 219 and temple-arm overmolded grommet 212 after the temple-arm overmolded grommet 212 is inserted into outlet 219. The features described in reference to FIGS. 2A-1 and 2A-2 (e.g., the outlet 219, a temple-arm overmolded grommet 212, and an FPC 216) are meant to complement the features discussed in their respective counterparts in FIGS. 1A and 1C. FIG. 2A-1 illustrates that the temple-arm overmolded grommet 212 has a depth range 201 (e.g., a depth into the outlet 219) that ranges between 0.5 mm-3 mm. FIG. 2A-2 further illustrates that the temple-arm grommet 212 has a grommet profile that corresponds to an outlet profile 221 of the outlet 219 such that the placement of the temple-arm overmolded grommet 212 within the outlet 219 is controlled. For example, the grommet can have a center region 222 that is recessed in comparison to the rest of grommet profile, and that recessed center region 222 can be configured to interface with a narrower region 224 of the outlet profile 221. In addition, the temple-arm overmolded grommet 212 is oversized relative to the outlet 219, which thereby produces an interference fit that aids in creating the fluid and dust seal. In some embodiments, the temple-arm overmolded grommet 212 is inserted into its predefined position in the outlet 219 in which an insertion force between 11-13 N is applied. The insertion force can be partially dictated by the shape of the grommet and the friction coefficient between the temple-arm overmolded grommet 212 and the outlet 219. In some embodiments, the kinetic coefficient of friction can range from 0.1-0.4. In some embodiments, the peak removal force (e.g., the force required to displace the temple-arm overmolded grommet 212 from hinge 218) is greater than the peak insertion force, which can be dictated by the profile of the temple-arm overmolded grommet 212.

In some embodiments, the temple arm 106 includes a recessed region in which the temple-arm overmolded grommet 212 resides. The recessed region is undersized relative to the temple-arm overmolded grommet 212, thereby producing an interference fit when the temple-arm overmolded grommet 212 is inserted into the recessed region. In some embodiments, the recessed region includes a recessed region inner diameter that is less than a recessed region outer diameter, and the temple-arm overmolded grommet 212 includes a temple-arm overmolded grommet 212 inner diameter (e.g., center region 222) that is less than the temple-arm overmolded grommet 212 outer diameter (e.g., grommet profile 219), and the recessed region inner diameter is configured to be aligned with the temple-arm overmolded grommet 212 inner diameter.

FIG. 2B illustrates examples of configurations of an overmolded grommet, in accordance with some embodiments. The temple-arm overmolded grommets 212-1 to 212-6 illustrate a plurality of optional configurations of the temple-arm overmolded grommet 212.

Each temple-arm overmolded grommet can vary in at least one parameter, such as a different friction coefficient, insertion force, and/or removal force. The insertion force is discussed above and the optional temple-arm overmolded grommets 212-1 to 212-6 include an insertion force range of 1-14 N during assembly. The insertion force range for each respective configuration is (i) temple-arm overmolded grommet 212-1 insertion force range is 1-2 N, (ii) temple-arm overmolded grommet 212-2 insertion force range is 11-13 N, (iii) temple-arm overmolded grommet 212-3 insertion force range is 8-10 N, (iv) temple-arm overmolded grommet 212-4 insertion force range is 4-6 N, (v) temple-arm overmolded grommet 212-5 insertion force range is 4-5 N, and (vi) temple-arm overmolded grommet 212-6 insertion force range is 11-13 N.

FIG. 2B further illustrates a predetermined distance between the temple-arm overmolded grommet 212 and a component 204 coupled to the FPC 216 such that the temple-arm overmolded grommet 212 is able to be manufactured onto the FPC 216 without impacting the components coupled to the FPC such as component 204. In some embodiments, the predetermined distance between the temple-arm overmolded grommet 212 and a component 204 is 2 mm-8 mm. In some embodiments, the temple-arm overmolded grommet 212 has a chamfer allowing for the component 204 to be slightly closer than the threshold distance.

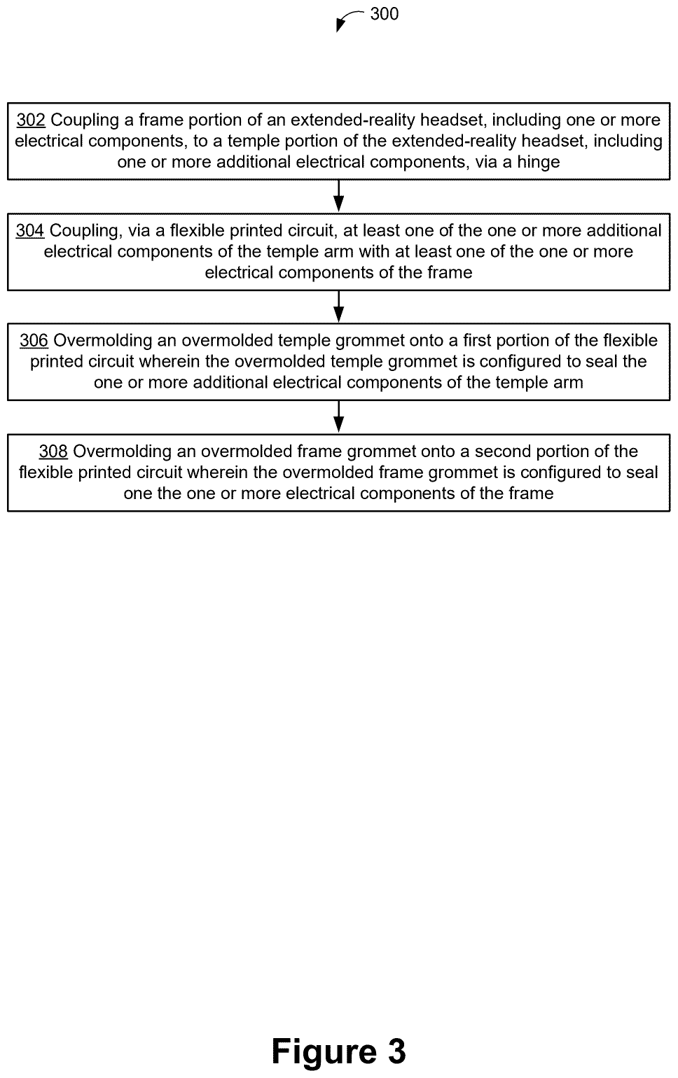

FIG. 3 shows an example method flow chart for manufacturing an overmolded grommet, in accordance with some embodiments. The method of manufacturing an extended-reality headset is described herein, including coupling one or more temple arms to a frame and overmolding one or more grommets onto an FPC integrated into the temple arms and frame.

(A1) FIG. 3 shows a flowchart of a method 300 for manufacturing an overmolded grommet, in accordance with some embodiments. In some embodiments, the method 300 includes coupling (302) a frame portion (e.g., frame 108) of an extended-reality headset (e.g., an extended-reality device 100), including one or more electrical components (e.g., a first set of components 142 coupled to the frame portion of the FPC 116), to a temple arm (e.g., a first temple arm 106a and a second temple arm 106b) of the extended-reality headset, including one or more additional electrical components (e.g., the second set of components 146 and the third set of components 144), via a hinge (e.g., hinge 118). The method 300 further includes coupling (304), via an FPC (e.g., FPC 116), at least one of the one or more additional electrical components of the temple arm with at least one of the one or more electrical components of the frame, overmolding (306) an overmolded temple grommet (e.g., temple-arm overmolded grommet 112) onto a first portion of the FPC wherein the overmolded temple grommet is configured to seal the one or more additional electrical components of the temple arm; and overmolding (308) an overmolded frame grommet (e.g., frame overmolded grommet 110) onto a second portion of the FPC wherein the overmolded frame grommet is configured to seal one of the one or more electrical components of the frame.

(B1) In some embodiments, the extended-reality headset (e.g., extended-reality device 100) includes a frame portion (e.g., frame 108) including one or more electrical components (e.g., a first set of components 142 coupled to the frame portion of the FPC 116) and a temple arm (e.g., a first temple arm 106a and a second temple arm 106b) including one or more additional electrical components (e.g., the second set of components 146 and the third set of components 144). The frame portion is coupled, via a hinge (e.g., hinge 118), to the temple arm, and an FPC (e.g., FPC 116) configured to couple at least one of the one or more additional electrical components of the temple arm with at least one of the one or more electrical components of the frame. The FPC further includes (i) an overmolded temple grommet (e.g., temple-arm overmolded grommet 112) configured to seal the one or more additional electrical components of the temple arm, and (ii) an overmolded frame grommet (e.g., frame overmolded grommet 110) configured to seal the one or more electrical components of the frame. The FPC is further configured to move with a movement (e.g., FIG. 1 illustrates that the temple arms 106a and 106b are capable of moving from an open to closed position via a hinge and vice versa) of the temple arm relative to the frame portion.

(B2) In some embodiments of B1, the temple arm is configured to operate between at least (i) a first positional state relative to the frame portion and (ii) a second positional state relative to the frame portion. The overmolded temple grommet is configured to seal the one or more additional electrical components of the temple arm when the temple arm is in either the first positional state or the second positional state, and the overmolded frame grommet is configured to seal the one or more electrical components of the frame when the temple arm is in either the first positional state or the second positional state. As discussed in FIG. 1A, the temple arms 106a and 106b are each configured to move between an opened and a closed position and while in the respective opened/closed position the frame and temple overmolded grommets 110 and 112 are configured to seal at least one or more electronic components of the temple arms 106a and 106b or the frame 108.

(B3) In some embodiments of any of B1 - B2, the FPC is configured to bend and straighten when operating between the first positional state and the second positional state (e.g., opened or closed as described in FIG. 1A), such that no more than 1-10 N of force is applied to either the overmolded temple grommet (e.g., frame overmolded grommet 110) and/or the overmolded frame grommet (e.g., temple-arm overmolded grommet 112). As described in FIG. 2A, the upward and downward pulling force should not exceed 1-10 N to prohibit damage to both the FPC 216 or the overmolded grommets (e.g., frame overmolded grommet 110 and temple-arm overmolded grommets 112). Furthermore, as described in FIG. 1, while the temple arms are opening and closing, the FPC 116 moves with the temple arms 106a and 106b and the frame 108.

(B4) In some embodiments of any of B1-B3, both the overmolded temple grommet and the overmolded frame grommet each encase respective portions of the FPC. As described in FIG. 1A, the frame and temple-arm overmolded grommets 110 and 112 cannot slide on the FPC 116 and they create a watertight seal between the FPC 116 and the frame and temple-arm overmolded grommets 110 and 112.

(B5) In some embodiments of any of B1-B4, the temple-arm grommet is further configured to seal liquid from interacting with the one or more additional electronic components, and the frame grommet is further configured to seal liquid from interaction with the one or more electronic components of the temple arm. As discussed with respect to FIG. 1A, the frame and temple-arm overmolded grommets 110 and 112 are configured to prohibit water contact with the one or more electronics coupled to the FPC 116 in both temple arms 106a and 106b and the frame 108 of the extended-reality device 100. In some embodiments, frame and temple-arm overmolded grommets 110 and 112 create an IP68 certified water seal.

(B6) In some embodiments of any of B1-B5, the temple arm includes a recessed region in which the temple-arm grommet resides, and the extended reality headset further includes a cowling (e.g., cowling 114) that is coupled to the temple arm and the cowling mechanically limits movement of the temple-arm grommet within the recessed region. As described in FIG. 1A, the cowling is coupled to the hinge 118 via one or more screws or an adhesive to prohibit the temple-arm overmolded grommet 112 from uncoupling from the hinge 118. The cowling 114 is self-aligning based on its design such that its features match the temple-arm overmolded grommet 112 and the hinge 118 portion. The cowling 114 is used to hold the temple-arm overmolded grommet 112 in place while the temple-arm overmolded grommet 112 is encased in the hinge.

(B7) In some embodiments of any of B1-B6, a coefficient of friction between a first outer portion of the overmolded temple-arm grommet and a first inner portion of the hinge is a non-zero value greater than 0.01. As discussed in FIG. 2A, the coefficient of friction between the temple-arm overmolded grommet 212 and the hinge 218 ranges from 0.1-0.4.

(B8) In some embodiments of any of B1-B7, the overmolded temple-arm grommet is inserted into a pass-through (e.g., through the open portion of the hinge 118) of the temple arm, and a peak insertion force of the overmolded temple-arm grommet into the pass-through of the temple arm is greater than or equal to 3 N. FIGS. 2A-1 and 2A-2 further describe the peak insertion force required to place the temple-arm overmolded grommet 212 into the hinge 218. In some embodiments, the peak insertion force includes the force it takes to securely fit the temple-arm overmolded grommet 212 into the opening of the hinge 218 such that the temple-arm overmolded grommet 212 and hinge 218 are coupled. In some embodiments, the temple-arm overmolded grommet 212 is oversized relative to the pass-through of the temple arm 106, thereby producing an interference fit. The interference fit aids in providing the seal described herein.

(B9) In some embodiments of any of B1-B8, a peak removal force is greater than a peak insertion force. As discussed in FIG. 2A, the peak removal force includes the force it takes to remove (e.g., de-couple) the overmolded temple-arm grommet 212 from the opening of the hinge 218 such that the overmolded temple-arm grommet 212 and hinge 218 are separated.

(B10) In some embodiments of any of B1-B9, the overmolded temple-arm grommet and the overmolded frame grommet are each constructed of at least one of silicon rubber and liquid rubber. As discussed in FIG. 1A, the frame and temple-arm overmolded grommets are constructed of a rubber-based material.

(B11) In some embodiments of any of B1-B10, a distance between a first portion of the overmolded temple-arm grommet and a first portion of the overmolded frame grommet is a value equal to or greater than 10 mm. In some embodiments, the first portions (e.g., the closest edges of the grommet facing each other) of the frame and temple-arm overmolded grommets 110 and 112 are the edges facing each other. In some embodiments, the distance between them is identified as 11.8 mm.

(B12) In some embodiments of any of B1-B11, at least one of the one or more additional electrical components is coupled to a first portion of the FPC at least 1 mm from a second portion of the overmolded temple-arm grommet. As discussed in FIG. 1C, the one or more electrical components (e.g., the second set of components 146) are 1 mm-5 mm away from the temple-arm overmolded grommet 112. In some embodiments, the one or more components are 1.75 mm away from the portion of the temple-arm overmolded grommet encased inside of the temple arm.

(B13) In some embodiments of any of B1-B12, a width of the overmolded temple-arm grommet is a value between 0.5 mm and 3 mm. As discussed in FIG. 2A, the temple-arm overmolded grommet 212 includes a width configured to provide a seal between the hinge 218 and the temple-arm overmolded grommet 212. In some embodiments, the maximum width of the overmolded temple-arm grommet is 2.4 mm.

(B14) In some embodiments of any of B1-B13, the overmolded temple-arm grommet has a different shape than the overmolded frame grommet. As described in FIG. 1A, the temple-arm overmolded grommet 112 and the frame overmolded grommet 110 are the same shape and size of two distinct shapes.

(B15) In some embodiments of any of B1-B14, the frame portion is a first frame portion at a first end of the frame, the temple arm is a first temple arm, and the extended-reality headset further includes a second frame portion at a second end of the frame opposite the first end of the frame, a second temple arm at a first end of a second temple arm coupled to the second frame portion via a hinge. The FPC is configured to couple one or more temple electrical components of the second temple arm with at least one of the one or more electrical components of the frame. The FPC further includes (i) another overmolded temple-arm grommet configured to seal the one or more additional electrical components of the second temple arm, and (ii) another overmolded frame grommet configured to seal one of the one or more electrical components of the frame. In some embodiments, the configuration of the hinge 118 and FPC 116 illustrated in FIG. 1A is placed at both connection points of the temple arms 106a and 106b as shown in FIG. 1A. In some embodiments, the components are mirrored such that the temple arms 106a and 106b fold into each other.

(B16) In some embodiments of any of B1-B15, the recessed region (e.g., the temple-arm recessed region in which the temple-arm grommet resides) is undersized relative to the temple-arm grommet, thereby producing an interference fit when the temple-arm grommet (e.g., temple-arm overmolded grommet 112) is inserted into the recessed region. FIGS. 2A-1 and 2A-2 illustrate the temple-arm overmolded grommet 112 inserted into the recessed region.

(B17) In some embodiments of any of B1-B16, the recessed region includes a recessed region inner diameter that is less than a recessed region outer diameter, the temple-arm grommet (e.g., temple-arm overmolded grommet 112) includes a temple-arm grommet inner diameter that is less than a temple-arm grommet outer diameter, and the recessed region inner diameter is configured to be aligned with the temple-arm grommet inner diameter.

(B18) In some embodiments of any of B1-B17, the flexible printed circuit is disposed in a temple arm and frame of the augmented-reality device.

(C1) In some embodiments, a method of manufacturing an extended-reality headset includes coupling a frame portion, including one or more electrical components, to a temple arm, including one or more additional electrical components, via a hinge, coupling, via an FPC, at least one of the one or more additional electrical components of the temple arm with at least one of the one or more electrical components of the frame, overmolding an overmolded temple-arm grommet onto a first portion of the FPC wherein the overmolded temple-arm grommet is configured to seal the one or more additional electrical components of the temple arm, overmolding an overmolded frame grommet onto a second portion of the FPC wherein the overmolded frame grommet is configured to seal one of the one or more electrical components of the frame.

The devices described above are further detailed below, including systems, wrist-wearable devices, headset devices, and smart textile-based garments. Specific operations described above may occur as a result of specific hardware; such hardware is described in further detail below. The devices described below are not limiting and features on these devices can be removed or additional features can be added to these devices. The different devices can include one or more analogous hardware components. For brevity, analogous devices and components are described below. Any differences in the devices and components are described below in their respective sections.

### Example Head-wearable Devices

FIGS. 4A, 4B-1, 4B-2, and 4C show example head-wearable devices, in accordance with some embodiments. Head-wearable devices can include, but are not limited to, the extended-reality device 100 (e.g., AR or smart eyewear devices, such as smart glasses, smart monocles, smart contacts, etc.), VR devices 410 (e.g., VR headsets, head-mounted displays (HMDs), etc.), or other ocularly coupled devices. The AR devices 400 and the VR devices 410 are instances of the head-wearable devices extended-reality device 100 described in reference to FIG. 1A-2B herein, such that the head-wearable device should be understood to have the features of the AR devices 400 and/or the VR devices 410, and vice versa. The AR devices 400 and the VR devices 410 can perform various functions and/or operations associated with navigating through user interfaces and selectively opening applications, as well as the functions and/or operations described above with reference to FIG. 1A-2B.

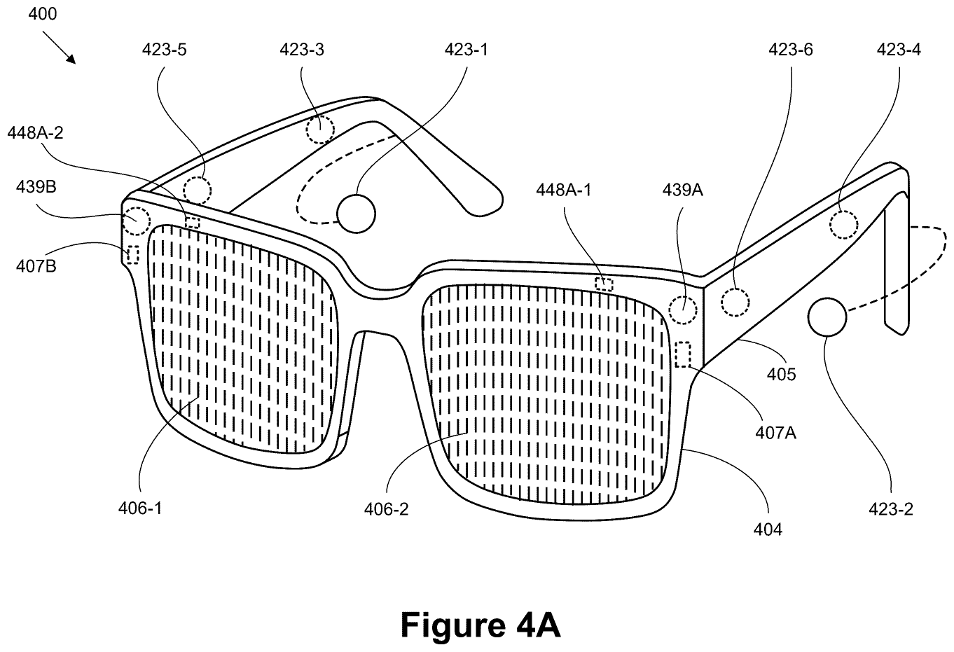

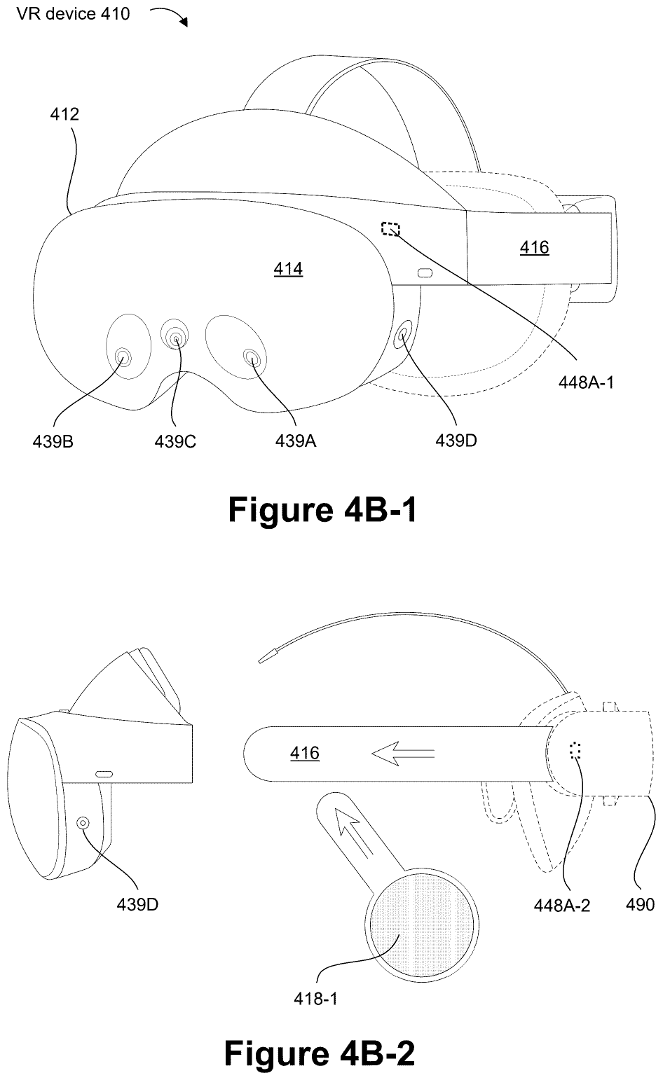

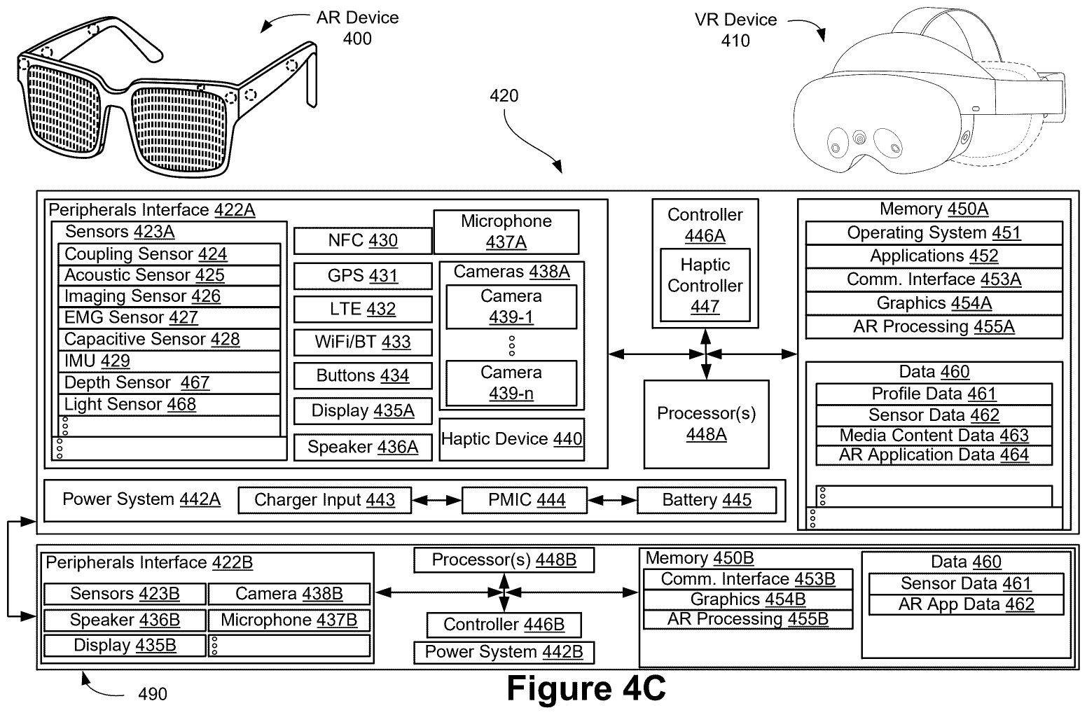

In some embodiments, an AR system includes an AR device 400 (as shown in FIG. 4A) and/or VR device 410 (as shown in FIGS. 4B-1-B-2). In some embodiments, the AR device 400 and the VR device 410 can include one or more analogous components (e.g., components for presenting interactive AR environments, such as processors, memory, and/or presentation devices, including one or more displays and/or one or more waveguides), some of which are described in more detail with respect to FIG. 4C. The head-wearable devices can use display projectors (e.g., display projector assemblies 407A and 407B) and/or waveguides for projecting representations of data to a user. Some embodiments of head-wearable devices do not include displays.

FIG. 4A shows an example visual depiction of the AR device 400 (e.g., which may also be described herein as augmented-reality glasses and/or smart glasses). The AR device 400 can work in conjunction with additional electronic components that are not shown in FIG. 4A, such as a wearable accessory device and/or an intermediary processing device, in electronic communication or otherwise configured to be used in conjunction with the AR device 400. In some embodiments, the wearable accessory device and/or the intermediary processing device may be configured to couple with the AR device 400 via a coupling mechanism in electronic communication with a coupling sensor 424, where the coupling sensor 424 can detect when an electronic device becomes physically or electronically coupled with the AR device 400. In some embodiments, the AR device 400 can be configured to couple to a housing (e.g., a portion of frame 404 or temple arms 405), which may include one or more additional coupling mechanisms configured to couple with additional accessory devices. The components shown in FIG. 4A can be implemented in hardware, software, firmware, or a combination thereof, including one or more signal-processing components and/or application-specific integrated circuits (ASICs).

The AR device 400 includes mechanical glasses components, including a frame 404 configured to hold one or more lenses (e.g., one or both lenses 406-1 and 406-2). One of ordinary skill in the art will appreciate that the AR device 400 can include additional mechanical components, such as hinges configured to allow portions of the frame 404 of the AR device 400 to be folded and unfolded, a bridge configured to span the gap between the lenses 406-1 and 406-2 and rest on the user's nose, nose pads configured to rest on the bridge of the nose and provide support for the AR device 400, earpieces configured to rest on the user's ears and provide additional support for the AR device 400, temple arms 405 configured to extend from the hinges to the earpieces of the AR device 400, and the like. One of ordinary skill in the art will further appreciate that some examples of the AR device 400 can include none of the mechanical components described herein. For example, smart contact lenses configured to present AR to users may not include any components of the AR device 400.

The lenses 406-1 and 406-2 can be individual displays or display devices (e.g., a waveguide for projected representations). The lenses 406-1 and 406-2 may act together or independently to present an image or series of images to a user. In some embodiments, the lenses 406-1 and 406-2 can operate in conjunction with one or more display projector assemblies 407A and 407B to present image data to a user. While the AR device 400 includes two displays, embodiments of this disclosure may be implemented in AR devices with a single near-eye display (NED) or more than two NEDs.

The AR device 400 includes electronic components, many of which will be described in more detail below with respect to FIG. 4C. Some example electronic components are illustrated in FIG. 4A, including sensors 423-1, 423-2, 423-3, 423-4, 423-5, and 423-6, which can be distributed along a substantial portion of the frame 404 of the AR device 400. The different types of sensors are described below in reference to FIG. 4C. The AR device 400 also includes a left camera 439A and a right camera 439B, which are located on different sides of the frame 404. And the eyewear device includes one or more processors 448A and 448B (e.g., an integral microprocessor, such as an ASIC) that are embedded into a portion of the frame 404.

FIGS. 4B-1 and 4B-2 show an example visual depiction of the VR device 410 (e.g., an HMD 412, also referred to herein as an AR headset, a head-wearable device, a VR headset, etc.). The HMD 412 includes a front body 414 and a frame 416 (e.g., a strap or band) shaped to fit around a user's head. In some embodiments, the front body 414 and/or the frame 416 includes one or more electronic elements for facilitating presentation of and/or interactions with an AR and/or VR system (e.g., displays, processors (e.g., processor 448A-1), IMUs, tracking emitter or detectors, sensors, etc.). In some embodiments, the HMD 412 includes output audio transducers (e.g., an audio transducer 418-1), as shown in FIG. 4B-2. In some embodiments, one or more components, such as the output audio transducer(s) 418-1 and the frame 416, can be configured to attach and detach (e.g., are detachably attachable) to the HMD 412 (e.g., a portion or all of the frame 416, and/or the output audio transducer 418-1), as shown in FIG. 4B-2. In some embodiments, coupling a detachable component to the HMD 412 causes the detachable component to come into electronic communication with the HMD 412. The VR device 410 includes electronic components, many of which will be described in more detail below with respect to FIG. 4C.

FIGS. 4B-1 to 4B-2 also show that the VR device 410 includes one or more cameras, such as the left camera 439A and the right camera 439B, which can be analogous to the left and right cameras on the frame 404 of the AR device 400. In some embodiments, the VR device 410 includes one or more additional cameras (e.g., cameras 439C and 439D), which can be configured to augment image data obtained by the cameras 439A and 439B by providing more information. For example, the camera 439C can be used to supply color information that is not discerned by cameras 439A and 439B. In some embodiments, one or more of the cameras 439A to 439D can include an optional IR cut filter configured to remove IR light from being received at the respective camera sensors.

The VR device 410 can include a housing 490 storing one or more components of the VR device 410 and/or additional components of the VR device 410. The housing 490 can be a modular electronic device configured to couple with the VR device 410 (or an AR device 400) and supplement and/or extend the capabilities of the VR device 410 (or an AR device 400). For example, the housing 490 can include additional sensors, cameras, power sources, processors (e.g., processor 448A-2), etc., to improve and/or increase the functionality of the VR device 410. Examples of the different components included in the housing 490 are described below in reference to FIG. 4C.

Alternatively, or in addition, in some embodiments, the head-wearable device, such as the VR device 410 and/or the AR device 400), includes, or is communicatively coupled to, another external device (e.g., a paired device), such as an HIPD and/or an optional neckband. The optional neckband can couple to the head-wearable device via one or more connectors (e.g., wired or wireless connectors). The head-wearable device and the neckband can operate independently without any wired or wireless connection between them. In some embodiments, the components of the head-wearable device and the neckband are located on one or more additional peripheral devices paired with the head-wearable device, the neckband, or some combination thereof. Furthermore, the neckband is intended to represent any suitable type or form of paired device. Thus, the following discussion of neckband may also apply to various other paired devices, such as smart watches, smart phones, wrist bands, other wearable devices, hand-held controllers, tablet computers, or laptop computers.

In some situations, pairing external devices, such as an intermediary processing device (e.g., an HIPD device, an optional neckband, and/or wearable accessory device) with the head-wearable devices (e.g., an AR device 400 and/or VR device 410) enables the head-wearable devices to achieve a similar form factor of a pair of glasses while still providing sufficient battery and computation power for expanded capabilities. Some, or all, of the battery power, computational resources, and/or additional features of the head-wearable devices can be provided by a paired device or shared between a paired device and the head-wearable devices, thus reducing the weight, heat profile, and form factor of the head-wearable devices overall while allowing the head-wearable devices to retain their desired functionality.

For example, the intermediary processing device (e.g., the HIPD) can allow components that would otherwise be included in a head-wearable device to be included in the intermediary processing device (and/or a wearable device or accessory device), thereby shifting a weight load from the user's head and neck to one or more other portions of the user's body. In some embodiments, the intermediary processing device has a larger surface area over which to diffuse and disperse heat to the ambient environment. Thus, the intermediary processing device can allow for greater battery and computation capacity than might otherwise have been possible on the head-wearable devices, standing alone. Because weight carried in the intermediary processing device can be less invasive to a user than weight carried in the head-wearable devices, a user may tolerate wearing a lighter eyewear device and carrying or wearing the paired device for greater lengths of time than the user would tolerate wearing a heavier eyewear device standing alone, thereby enabling an AR environment to be incorporated more fully into a user's day-to-day activities.

In some embodiments, the intermediary processing device is communicatively coupled with the head-wearable device and/or to other devices. The other devices may provide certain functions (e.g., tracking, localizing, depth mapping, processing, storage, etc.) to the head-wearable device. In some embodiments, the intermediary processing device includes a controller and a power source. In some embodiments, sensors of the intermediary processing device are configured to sense additional data that can be shared with the head-wearable devices in an electronic format (analog or digital).

The controller of the intermediary processing device processes information generated by the sensors on the intermediary processing device and/or the head-wearable devices. The intermediary processing device, such as an HIPD, can process information generated by one or more sensors of its sensors and/or information provided by other communicatively coupled devices. For example, a head-wearable device can include an IMU, and the intermediary processing device (neckband and/or an HIPD) can compute all inertial and spatial calculations from the IMUs located on the head-wearable device.

AR systems may include a variety of types of visual feedback mechanisms. For example, display devices in the AR devices 400 and/or the VR devices 410 may include one or more liquid-crystal displays (LCDs), light emitting diode (LED) displays, organic LED (OLED) displays, and/or any other suitable type of display screen. AR systems may include a single display screen for both eyes or may provide a display screen for each eye, which may allow for additional flexibility for varifocal adjustments or for correcting a refractive error associated with the user's vision. Some AR systems also include optical subsystems having one or more lenses (e.g., conventional concave or convex lenses, Fresnel lenses, or adjustable liquid lenses) through which a user may view a display screen. In addition to or instead of using display screens, some AR systems include one or more projection systems. For example, display devices in the AR device 400 and/or the VR device 410 may include micro-LED projectors that project light (e.g., using a waveguide) into display devices, such as clear combiner lenses that allow ambient light to pass through. The display devices may refract the projected light toward a user's pupil and may enable a user to simultaneously view both AR content and the real world. AR systems may also be configured with any other suitable type or form of image projection system. As noted, some AR systems may, instead of blending an artificial reality with actual reality, substantially replace one or more of a user's sensory perceptions of the real world with a virtual experience.

While the example head-wearable devices are respectively described herein as the AR device 400 and the VR device 410, either or both of the example head-wearable devices described herein can be configured to present fully-immersive VR scenes presented in substantially all of a user's field of view, additionally or alternatively to, subtler augmented-reality scenes that are presented within a portion, less than all, of the user's field of view.

In some embodiments, the AR device 400 and/or the VR device 410 can include haptic feedback systems. The haptic feedback systems may provide various types of cutaneous feedback, including vibration, force, traction, shear, texture, and/or temperature. The haptic feedback systems may also provide various types of kinesthetic feedback, such as motion and compliance. The haptic feedback can be implemented using motors, piezoelectric actuators, fluidic systems, and/or a variety of other types of feedback mechanisms. The haptic feedback systems may be implemented independently of other AR devices, within other AR devices, and/or in conjunction with other AR devices (e.g., wrist-wearable devices that may be incorporated into headwear, gloves, body suits, handheld controllers, environmental devices (e.g., chairs or floormats), and/or any other type of device or system, such as a wrist-wearable device, an HIPD, smart textile-based garment, etc.), and/or other devices described herein.

FIG. 4C illustrates a computing system 420 and an optional housing 490, each of which shows components that can be included in a head-wearable device (e.g., the AR device 400 and/or the VR device 410). In some embodiments, more or fewer components can be included in the optional housing 490 depending on practical restraints of the respective head-wearable device being described. Additionally, or alternatively, the optional housing 490 can include additional components to expand and/or augment the functionality of a head-wearable device.

In some embodiments, the computing system 420 and/or the optional housing 490 can include one or more peripheral interfaces 422A and 422B, one or more power systems 442A and 442B (including charger input 443, PMIC 444, and battery 445), one or more controllers 446A and/or 446B (including one or more haptic controllers 447), one or more processors 448A and 448B (as defined above, including any of the examples provided), and memory 450A and 450B, which can all be in electronic communication with each other. For example, the one or more processors 448A and/or 448B can be configured to execute instructions stored in the memory 450A and/or 450B, which can cause a controller of the one or more controllers 446A and/or 446B to cause operations to be performed at one or more peripheral devices of the peripherals interfaces 422A and/or 422B. In some embodiments, each operation described can occur based on electrical power provided by the power system 442A and/or 442B.

In some embodiments, the peripherals interface 422A can include one or more devices configured to be part of the computing system 420, many of which have been defined above and/or described with respect to wrist-wearable devices. For example, the peripherals interfaces can include one or more sensors 423A. Some example sensors include one or more coupling sensors 424, one or more acoustic sensors 425, one or more imaging sensors 426, one or more EMG sensors 427, one or more capacitive sensors 428, and/or one or more IMUs 429. In some embodiments, the sensors 423A further include depth sensors 467, light sensors 468 and/or any other types of sensors defined above or described with respect to any other embodiments discussed herein.

In some embodiments, the peripherals interface can include one or more additional peripheral devices, including one or more NFC devices 430, one or more GPS devices 431, one or more LTE devices 432, one or more Wi-Fi and/or Bluetooth devices 433, one or more buttons 434 (e.g., including buttons that are slidable or otherwise adjustable), one or more displays 435A, one or more speakers 436A, one or more microphones 437A, one or more cameras 438A (e.g., including a first camera 439-1 through camera 439-n, which are analogous to the left camera 439A and/or the right camera 439B), one or more haptic devices 440; and/or any other types of peripheral devices defined above or described with respect to any other embodiments discussed herein.

The head-wearable devices can include a variety of types of visual feedback mechanisms (e.g., presentation devices). For example, display devices in the AR device 400 and/or the VR device 410 can include one or more LCDs, LED displays, OLED displays, micro-LEDs, and/or any other suitable types of display screens. The head-wearable devices can include a single display screen (e.g., configured to be seen by both eyes), and/or can provide separate display screens for each eye, which can allow for additional flexibility for varifocal adjustments and/or for correcting a refractive error associated with the user's vision. Some embodiments of the head-wearable devices also include optical subsystems having one or more lenses (e.g., conventional concave or convex lenses, Fresnel lenses, or adjustable liquid lenses) through which a user can view a display screen. For example, respective displays 435A can be coupled to each of the lenses 406-1 and 406-2 of the AR device 400. The displays 435A coupled to each of the lenses 406-1 and 406-2 can act together or independently to present an image or series of images to a user. In some embodiments, the AR device 400 and/or the VR device 410 includes a single display 435A (e.g., an NED) or more than two displays 435A.

In some embodiments, a first set of one or more displays 435A can be used to present an augmented-reality environment, and a second set of one or more display devices 435A can be used to present a VR environment. In some embodiments, one or more waveguides are used in conjunction with presenting AR content to the user of the AR device 400 and/or the VR device 410 (e.g., as a means of delivering light from a display projector assembly and/or one or more displays 435A to the user's eyes). In some embodiments, one or more waveguides are fully or partially integrated into the AR device 400 and/or the VR device 410. Additionally, or alternatively to display screens, some AR systems include one or more projection systems. For example, display devices in the AR device 400 and/or the VR device 410 can include micro-LED projectors that project light (e.g., using a waveguide) into display devices, such as clear combiner lenses that allow ambient light to pass through. The display devices can refract the projected light toward a user's pupil and can enable a user to simultaneously view both AR content and the real world. The head-wearable devices can also be configured with any other suitable type or form of image projection system. In some embodiments, one or more waveguides are provided additionally or alternatively to the one or more display(s) 435A.

In some embodiments of the head-wearable devices, ambient light and/or a real-world live view (e.g., a live feed of the surrounding environment that a user would normally see) can be passed through a display element of a respective head-wearable device presenting aspects of the AR system. In some embodiments, ambient light and/or the real-world live view can be passed through a portion of less than all of an AR environment presented within a user's field of view (e.g., a portion of the AR environment co-located with a physical object in the user's real-world environment that is within a designated boundary (e.g., a guardian boundary) configured to be used by the user while they are interacting with the AR environment). For example, a visual user interface element (e.g., a notification user interface element) can be presented at the head-wearable devices, and an amount of ambient light and/or the real-world live view (e.g., 15% - 50% of the ambient light and/or the real-world live view) can be passed through the user interface element, such that the user can distinguish at least a portion of the physical environment over which the user interface element is being displayed.

The head-wearable devices can include one or more external displays 435A for presenting information to users. For example, an external display 435A can be used to show a current battery level, network activity (e.g., connected, disconnected, etc.), current activity (e.g., playing a game, in a call, in a meeting, watching a movie, etc.), and/or other relevant information. In some embodiments, the external displays 435A can be used to communicate with others. For example, a user of the head-wearable device can cause the external displays 435A to present a do-not-disturb notification. The external displays 435A can also be used by the user to share any information captured by the one or more components of the peripherals interface 422A and/or generated by the head-wearable device (e.g., during operation and/or performance of one or more applications).

The memory 450A can include instructions and/or data executable by one or more processors 448A (and/or processors 448B of the housing 490) and/or a memory controller of the one or more controllers 446A (and/or controller 446B of the housing 490). The memory 450A can include one or more operating systems 451; one or more applications 452; one or more communication interface modules 453A; one or more graphics modules 454A; one or more AR processing modules 455A; and/or any other types of modules or components defined above or described with respect to any other embodiments discussed herein.

The data 460 stored in memory 450A can be used in conjunction with one or more of the applications and/or programs discussed above. The data 460 can include profile data 461; sensor data 462; media content data 463; AR application data 464; and/or any other types of data defined above or described with respect to any other embodiments discussed herein.

In some embodiments, the controller 446A of the head-wearable devices processes information generated by the sensors 423A on the head-wearable devices and/or another component of the head-wearable devices and/or communicatively coupled with the head-wearable devices (e.g., components of the housing 490, such as components of peripherals interface 422B). For example, the controller 446A can process information from the acoustic sensors 425 and/or image sensors 426. For each detected sound, the controller 446A can perform a direction-of-arrival estimation to estimate a direction from which the detected sound arrived at a head-wearable device. As one or more of the acoustic sensors 425 detects sounds, the controller 446A can populate an audio data set with the information (e.g., represented by sensor data 462).

In some embodiments, a physical electronic connector can convey information between the head-wearable devices and another electronic device, and/or between one or more processors 448A of the head-wearable devices and the controller 446A. The information can be in the form of optical data, electrical data, wireless data, or any other transmittable data form. Moving the processing of information generated by the head-wearable devices to an intermediary processing device can reduce weight and heat in the eyewear device, making it more comfortable and safer for a user. In some embodiments, an optional accessory device (e.g., an electronic neckband or an HIPD) is coupled to the head-wearable devices via one or more connectors. The connectors can be wired or wireless connectors and can include electrical and/or non-electrical (e.g., structural) components. In some embodiments, the head-wearable devices and the accessory device can operate independently without any wired or wireless connection between them.

The head-wearable devices can include various types of computer vision components and subsystems. For example, the AR device 400 and/or the VR device 410 can include one or more optical sensors such as two-dimensional (2D) or 3D cameras, ToF depth sensors, single-beam or sweeping laser rangefinders, 3D LiDAR sensors, and/or any other suitable type or form of optical sensor. A head-wearable device can process data from one or more of these sensors to identify a location of a user and/or aspects of the user's real-world physical surroundings, including the locations of real-world objects within the real-world physical surroundings. In some embodiments, the methods described herein are used to map the real world, to provide a user with context about real-world surroundings, and/or to generate interactable virtual objects (which can be replicas or digital twins of real-world objects that can be interacted within an AR environment), among a variety of other functions. For example, FIGS. 4B-1 and 4B-2 show the VR device 410 having cameras 439A - 439D, which can be used to provide depth information for creating a voxel field and a 2D mesh to provide object information to the user to avoid collisions.

The optional housing 490 can include analogous components to those described above with respect to the computing system 420. For example, the optional housing 490 can include a respective peripherals interface 422B including more or fewer components to those described above with respect to the peripherals interface 422A. As described above, the components of the optional housing 490 can be used to augment and/or expand on the functionality of the head-wearable devices. For example, the optional housing 490 can include respective sensors 423B, speakers 436B, displays 435B, microphones 437B, cameras 438B, and/or other components to capture and/or present data.

Similarly, the optional housing 490 can include one or more processors 448B, controllers 446B, and/or memory 450B (including respective communication interface modules 453B; one or more graphics modules 454B; one or more AR processing modules 455B, etc.) that can be used individually and/or in conjunction with the components of the computing system 420.

The techniques described above in FIG. 4A-4C can be used with different head-wearable devices. In some embodiments, the head-wearable devices (e.g., the AR device 400 and/or the VR device 410) can be used in conjunction with one or more wearable devices.

Any data collection performed by the devices described herein and/or any devices configured to perform or cause the performance of the different embodiments described above in reference to any of the Figures, hereinafter the “devices,” is done with user consent and in a manner that is consistent with all applicable privacy laws. Users are given options to allow the devices to collect data, as well as the option to limit or deny collection of data by the devices. A user is able to opt in or opt out of any data collection at any time. Further, users are given the option to request the removal of any collected data.

It will be understood that, although the terms “first,” “second,” etc., may be used herein to describe various elements, these elements should not be limited by these terms. These terms are only used to distinguish one element from another.

The terminology used herein is for the purpose of describing particular embodiments only and is not intended to be limiting of the claims. As used in the description of the embodiments and the appended claims, the singular forms “a,” “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the term “if” can be construed to mean “when” or “upon” or “in response to determining” or “in accordance with a determination” or “in response to detecting,” that a stated condition precedent is true, depending on the context. Similarly, the phrases “if it is determined [that a stated condition precedent is true]” or “if [a stated condition precedent is true]” or “when [a stated condition precedent is true]” can be construed to mean “upon determining” or “in response to determining” or “in accordance with a determination” or “upon detecting” or “in response to detecting” that the stated condition precedent is true, depending on the context.

The foregoing description, for purpose of explanation, has been described with reference to specific embodiments. However, the illustrative discussions above are not intended to be exhaustive or to limit the claims to the precise forms disclosed. Many modifications and variations are possible in view of the above teachings. The embodiments were chosen and described in order to best explain principles of operation and practical applications, to thereby enable others skilled in the art.

What is claimed is:

1. An augmented-reality headset comprising:
a frame portion including one or more electrical components;
a temple arm including one or more additional electrical components, wherein the frame portion is coupled, via a hinge, to the temple arm;
a flexible printed circuit (FPC) configured to couple at least one of the one or more additional electrical components of the temple arm with at least one of the one or more electrical components of the frame portion, wherein the FPC comprises:
(i) an overmolded temple grommet configured to create a first seal for the one or more additional electrical components of the temple arm, and
(ii) an overmolded frame grommet configured to create a second seal for the one the one or more electrical components of the frame portion; and
the FPC is further configured to maintain the first seal and the second seal during movement of the temple arm relative to the frame portion.

2. The augmented-reality headset of claim 1, wherein the temple arm is configured to operate between at least (i) a first positional state relative to the frame portion and (ii) a second positional state relative to the frame portion, wherein:
the overmolded temple grommet is configured to seal the one or more additional electrical components of the temple arm when the temple arm is in either the first positional state or the second positional state; and
the overmolded frame grommet is configured to seal the one or more electrical components of the frame portion when the temple arm is in either the first positional state or the second positional state.

3. The augmented-reality headset of claim 2, wherein the FPC is configured to bend and straighten when operating between the first positional state and the second positional state, such that no more than 1-10 N of force is applied to either the overmolded temple grommet and/or the overmolded frame grommet.

4. The augmented-reality headset of claim 1, wherein both the overmolded temple grommet and the overmolded frame grommet each encase respective portions of the FPC.

5. The augmented-reality headset of claim 1, wherein the overmolded temple grommet is further configured to seal liquid from interacting with the one or more additional electrical components of the temple arm, and the overmolded frame grommet is further configured to seal liquid from interaction with the one or more electrical components.

6. The augmented-reality headset of claim 1, wherein the temple arm includes a recessed region in which the overmolded temple grommet resides, and the augmented-reality headset further includes a cowling that is coupled to the temple arm and the cowling mechanically limits movement of the overmolded temple grommet within the recessed region.

7. The augmented-reality headset of claim 6, wherein the recessed region is undersized relative to the overmolded temple grommet thereby producing an interference fit when the overmolded temple grommet is inserted into the recessed region.

8. The augmented-reality headset of claim 6, wherein:
the recessed region includes a recessed region inner diameter that is less than a recessed region outer diameter,
the overmolded temple grommet includes a temple grommet inner diameter that is less than a temple grommet outer diameter, and
the recessed region inner diameter is configured to be aligned with the temple grommet inner diameter.

9. The augmented-reality headset of claim 1, wherein a coefficient of friction between a first outer portion of the overmolded temple grommet and a first inner portion of the hinge is a non-zero value greater than 0.01.

10. The augmented-reality headset of claim 1, wherein the overmolded temple grommet is inserted into a pass-through of the temple arm and a peak insertion force of the overmolded temple grommet into the pass-through of the temple arm is greater than or equal to 3 N.

11. The augmented-reality headset of claim 10, wherein a peak removal force is greater than the peak insertion force.

12. The augmented-reality headset of claim 1, wherein the overmolded temple grommet and the overmolded temple grommet are each constructed of at least one of silicon rubber and liquid rubber.

13. The augmented-reality headset of claim 1, wherein a distance between a first portion of the overmolded temple grommet and a first portion of the overmolded frame grommet is a value equal to or greater than 10 mm.

14. The augmented-reality headset of claim 1, wherein at least one of the one or more additional electrical components are coupled to a first portion of the FPC at least one mm from a second portion of the overmolded temple grommet.

15. The augmented-reality headset of claim 1, wherein a width of the overmolded temple grommet is a value between 0.5 mm and 3 mm.

16. The augmented-reality headset of claim 1, wherein the overmolded temple grommet has a different shape than the overmolded frame grommet.

17. The augmented-reality headset of claim 1, wherein the frame portion is a first frame portion at a first end of the frame portion, the temple arm is a first temple arm, and the augmented-reality headset further includes:
a second frame portion at a second end of the frame portion opposite a first end of the frame portion;
a second temple arm at a first end of a second temple arm coupled to the second frame portion via a hinge; and
the FPC is configured to couple one or more temple electrical components of the second temple arm with at least one of the one or more electrical components of the frame portion wherein the FPC further comprises:
(i) another overmolded temple grommet configured to seal the one or more additional electrical components of the second temple arm, and
(ii) another overmolded frame grommet configured to seal one the one or more electrical components of the frame portion.

18. A method of assembling an augmented-reality headset, comprising:
coupling a frame portion of an extended-reality headset, including one or more electrical components, to a temple arm of the extended-reality headset, including one or more additional electrical components, via a hinge;
coupling, via a flexible printed circuit (FPC), at least one of the one or more additional electrical components of the temple arm with at least one of the one or more electrical components of the frame portion, wherein the FPC comprises:
an overmolded temple grommet configured to create a first seal for the one or more additional electrical components of the temple arm, and
an overmolded frame grommet configured to create a second seal for the one the one or more electrical components of the frame portion.

19. A flexible printed circuit comprising:
an overmolded temple grommet configured to create a first seal for one or more additional electrical components of a temple arm of an augmented-reality device, and
an overmolded frame grommet configured to create a second seal for at least one of one or more electrical components of a frame of an augmented-reality device, wherein:
a flexible printed circuit is further configured to maintain the first seal and the second seal during movement of the temple arm relative to the frame.

20. The flexible printed circuit of claim 19, wherein:
the flexible printed circuit is disposed in a temple arm and frame of the augmented-reality device.
